(19) United States
(12) Patent Application Publication
(10) Pub. No.: US 2013/0127675 A1
(43) Pub. Date: May 23, 2013

(54) ELECTROMAGNETIC WAVE SENSOR AND A METHOD FOR FABRICATING IT

(71) Applicants: Juha MALLAT, HELSINKI (FI); Andrey GENERALOV, ESPOO (FI); Dmitry LYUBCHENKO, HELSINKI (FI); Victor OVCHINNIKOV, ESPOO (FI); Antti RAISANEN, ESPOO (FI)

(72) Inventors: Juha MALLAT, HELSINKI (FI); Andrey GENERALOV, ESPOO (FI); Dmitry LYUBCHENKO, HELSINKI (FI); Victor OVCHINNIKOV, ESPOO (FI); Antti RAISANEN, ESPOO (FI)

(73) Assignee: AALTO UNIVERSITY FOUNDATION, AALTO (FI)

(21) Appl. No.: 13/298,579

(22) Filed: Nov. 17, 2011

(51) Int. Cl. G01R 29/08; H05K 13/00; H01P 11/00

(52) U.S. Cl. 343/703; 29/600; 29/601

(57) ABSTRACT

A sensor for measuring electromagnetic power in a dielectric waveguide structure includes an antenna element for detecting heating caused by electromagnetic power absorbed into the antenna element. A membrane forming at least partially a thermally insulating layer is implemented on a surface of the dielectric waveguide structure being a substrate for the sensor. The antenna element is implemented on a surface of the membrane and the antenna element is at least partially thermally insulated with a cavity from the substrate. A method for fabricating the sensor is also described.

### TECHNICAL FIELD

The invention concerns in general the technical field of sensors for measuring electromagnetic power. Especially the invention concerns a power sensor implemented in a dielectric waveguide structure.

### BACKGROUND OF THE INVENTION

Multiple different types of sensors for measuring power of electromagnetic waves have been developed. Basically the RF power measurement is based on two types of sensors used. A first type is a rectification-type sensor and a second type is a thermal-type sensor.

In a rectification-type sensor technology the sensor uses a frequency down-conversion process converting a high frequency to a low frequency through characteristics of a non-linear device, such as a diode, to take RF power measurements. Alternatively, the measurements with diode sensors can be based on a conversion of RF signal into a DC voltage, which is measured. The main problem with this type of sensors is that the signal conversion is a lossy process and causes noise, which in turn has an effect on the measurement resuit.

The second type of sensor technology for RF power measurement is a thermal-type sensor, which uses resistance changes or dielectric permittivity changes due to temperature changes. There are several types of thermal-type sensors. Some examples of the thermal-type sensor are a thermistor and a thermocouple sensor. The disadvantage in both the thermistor and the thermocouple sensors is the nonlinear characteristics, especially at high level of power.

One specific type of thermistor sensor is a so called bolometer power sensor. It converts unknown RF power to heat and detects that heat. In other words it measures heat generated by the RF energy. Bolometers are used especially in mm and sub-mm wave range. Thus, they are widely applied in radio astronomy.

However, bolometers used for radio astronomy are fabricated from multiple structural elements and are aimed at the highest possible sensitivity requiring cryogenic cooling. Thus, the fabrication and use of those are complicated and those bolometers have also limitations of maximum power applied.

Furthermore, a waveguide is a structure for guiding waves, such as electromagnetic waves or sound waves. Here we concentrate on waveguides for guiding electromagnetic waves. Originally, the waveguide meant a hollow conductive metal pipe used to carry high frequency radio waves, particularly microwaves. Today, there are different types of waveguides for different frequency ranges and different applications. One class of waveguides is a dielectric waveguide. One type of a dielectric waveguide is a dielectric rod waveguide, also known as DRW. Dielectric rod waveguides are successfully used as basic transmission lines in the millimeter wave integrated circuits. In comparison with a metal waveguide, a DRW has less attenuation. Another advantage of the DRW is a convenience in integrating different components into the DRW using standard semiconductor techniques.

In order to utilize waveguides in transmitting power between different entities it is important to control the power level in transmission. To achieve this one needs to measure the power in the waveguide as exactly as possible. Due to the novel application areas of waveguides, for example in high frequencies, the requirements for power sensors applied with waveguides have tightened. Also the size of waveguides used in mm wave range transmission creates limitations to power sensors applicable.

### SUMMARY OF THE INVENTION

An objective of the invention is to present a sensor and a fabrication method for a sensor for measuring electromagnetic power in a dielectric waveguide structure. Another objective of the invention is that the sensor for measuring electromagnetic power in a dielectric waveguide structure is able to mitigate the environmental effects to the measurement and also the effects of the absorption of the electromagnetic wave into the waveguide structure.

The objectives of the invention are achieved by arranging an antenna element monolithically with the waveguide structure. More specifically, the objectives of the invention are achieved by introducing a power sensor structure representing the heating element and sensing element in the same time.

According to some aspects of the invention the sensor for measuring electromagnetic power in a dielectric waveguide structure comprises an antenna element for detecting heating caused by electromagnetic power absorbed into the antenna element. A membrane forming at least partially a thermally and/or electrically insulating layer is implemented on a surface of the dielectric waveguide structure being a substrate for the sensor. The antenna element is implemented on a surface of the membrane. The antenna element is at least partially thermally insulated from the substrate with a cavity being e.g. air gap or vacuum space. According to some aspects of the invention the antenna element is metallic.

Some aspects of the invention introduce a sensor further comprising a reference resistor for detecting the temperature change caused by environmental changes implemented on a surface of a membrane. Some aspects of the invention disclose a sensor wherein said reference resistor is at least partially in a direct thermal contact with the substrate through said membrane.

Further, some aspects of the invention introduce an antenna element and a reference resistor, which are manufactured of the same metallic material.

Some aspects of the invention introduce that the membrane is silicon dioxide (SiO₂). Further, the depth of the thermally insulating cavity/air gap is of the order of 50 μm.

According to an aspect of the invention the method for fabricating a sensor for measuring electromagnetic power in a dielectric waveguide structure comprises capping at least partially the dielectric waveguide structure with a membrane, the dielectric waveguide structure forming a substrate for the sensor; implementing an antenna element at least partially on a surface of the membrane; etching the dielectric waveguide structure at least partially below the antenna element in order to thermally insulate the antenna element from the substrate by forming an insulating cavity.

Some aspects of the invention comprise an inductively coupled plasma reactive ion etching (ICP-RIE) method for forming the cavity/air gap. Some further aspects of the invention introduce a wet etching of silicon for forming the cavity/air cap.

A sensor according to the invention is characterized by the features recited in the characterizing part of the independent claim directed to a sensor.

A method for fabricating a sensor according to the invention is characterized by the features recited in the characterizing part of the independent claim directed to a method.

The exemplary embodiments of the invention presented in this patent application are not to be interpreted to pose limitations to the applicability of the appended claims. The verb “to comprise” is used in this patent application as an open limitation that does not exclude the existence of also unrecited features. The features recited in depending claims are mutually freely combinable unless otherwise explicitly stated.

The novel features which are considered as characteristic of the invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF DRAWINGS

FIG. 1 illustrates a sensor structure according to an embodiment of the invention,

FIG. 2 illustrates a dependence of the heating of the antenna element in response to the depth of the gap (the lateral undercut as a parameter)

FIG. 3 illustrates a sensor structure according to another embodiment of the invention,

FIG. 4a-4c illustrate the fabrication steps of the method according to the invention.

### DETAILED DESCRIPTION OF THE INVENTION AND ITS ADVANTAGEOUS EMBODIMENTS

In order to gain full use of waveguide structures in electromagnetic transmission it is essential to be able to measure the power of the electromagnetic wave in the waveguide as accurately as possible. The present invention discloses a novel and inventive power sensor structure. The novel design enables the power measurements in higher power levels and frequencies than has been possible with the known power sensor structures so far. According to the invention the structure of the dielectric waveguide is utilized as a substrate for sensor element.

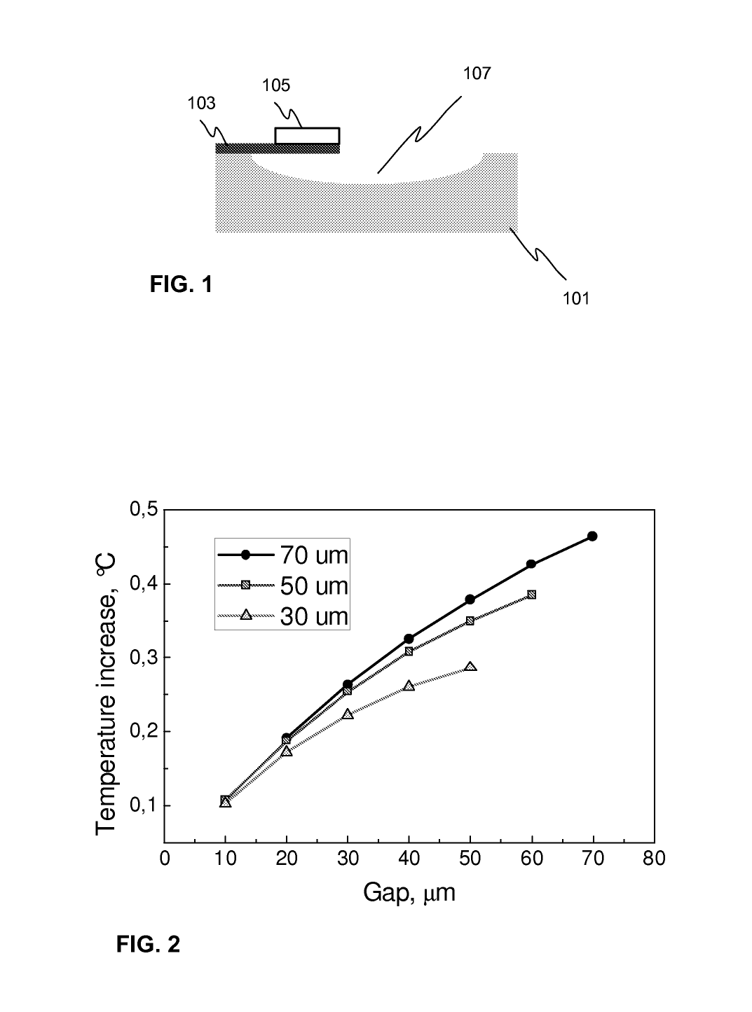

Now the invention is discussed by referring to FIG. 1 disclosing an embodiment of the sensor structure according to the invention. The sensor structure is implemented at least partially into the dielectric waveguide. In practice, this means that the silicon forming the waveguide is utilized in the power sensor structure as a substrate element 101 by means of which the sensor element can be implemented monolithically into the dielectric waveguide structure. According to the invention the sensor element is a lossy antenna structure, e.g. a bolometer. According to at least some embodiments of the invention the lossy antenna structure is metallic, such as chromium.

The dielectric waveguide structure offers an applicable substrate 101 for the sensor structure when considering the fabrication of the structure according to the invention with standard semiconductor techniques. According to the invention a thermal insulation is arranged between the substrate 101 and a lossy antenna element 105 operating as a sensor in the dielectric waveguide. The thermal insulation is at least partially arranged by means of a membrane 103. The material of the membrane 103 according to an embodiment of the invention is silicon dioxide (SiO₂), but could be any other dielectric material. Silicon dioxide (SiO₂), however is advantageous in a sense that it is common and easy-to-work-with material in microfabrication. The membrane 103 enables insulation between the lossy antenna element 105 operating as a power sensor and the waveguide. Thus, the speed and the sensitivity of the sensor can be improved even in high frequencies. Furthermore, the function of the membrane 103 is also to hold the metallic structure above the insulating cavity, e.g. air gap, which will discussed later.

According to an embodiment of the invention the insulating membrane 103 is fixed only on one edge of the dielectric waveguide structure i.e. forming a cantilever structure. This formation has several advantages. Firstly, it simplifies the fabrication process of the sensor. Additionally, the speed and sensitivity of the sensor are improved as already mentioned. The fix of the insulating membrane 103 with the dielectric waveguide structure can also be implemented in other ways. Any structure that allows the formation of an insulating cavity between the insulating membrane 103 and the substrate 101 can be implemented.

In order to further improve the thermal insulation of the antenna element and thus the speed and sensitivity of the sensor as well as the stability of the sensor structure, an insulating cavity 107 is arranged between the elements of the antenna 105 and the substrate 101 wherein a membrane 103 is arranged between the mentioned elements. This is advantageously achieved by etching silicon below the cantilever-type membrane. The insulating cavity formed in that manner cuts the path of thermal conductance and thus improves the operation of the sensor according to the invention. The insulating cavity can be an air gap or a vacuum space, for example.

FIG. 1 illustrates only one branch of the lossy antenna element for clarity reasons. However, the similar structural arrangement is applicable if the antenna element comprises more than one branch.

It is considered that the unknown energy to be measured travels inside the dielectric waveguide. In the dielectric waveguide the metal structure is absorbing at least part of the energy. As a result, the absorbed energy in the metal structure dissipates into heat, which causes a change of resistance of the structure. By measuring the resistance change using standard electrical engineering tools one can thereby define the amount of energy travelling in the dielectric waveguide.

FIG. 2 discloses the dependence of the temperature increase in the sensor of FIG. 1 in response of the size of the undercut below the membrane (i.e. the lateral undercut as a parameter). It can be seen that by increasing the undercut, the temperature increases in the sensor. Thus, the sensor becomes more sensitive in detecting the changes in the temperature, i.e., absorption of the electromagnetic wave energy. However, for practical and technological reasons (e.g. originating from the manufacturing i.e. etching process) an acceptable value for undercut is about 50 μm, which provides a reasonable heating in the sensor for measurement purposes.

According to another embodiment of the invention a reference resistor is arranged monolithically with the lossy antenna structure, which antenna structure is, according to at least some embodiments of the invention, metallic. In the embodiment the lossy antenna structure used as the electromagnetic power sensor is the same as in the first embodiment. The reference resistor is configured to measure at least the environmental temperature by detecting the change in resistance in response to the change in temperature. By means of the reference resistor the effect of environmental temperature change can be eliminated and thus the power measurement accuracy can be improved.

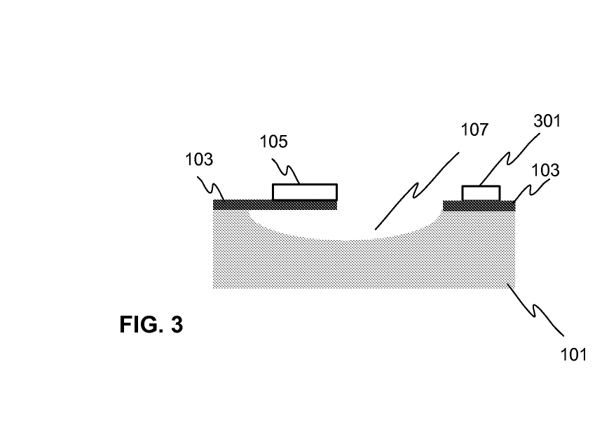

FIG. 3 illustrates the reference resistor 301 in dielectric waveguide structure. The structure of the dielectric waveguide is used as a substrate 101 for the reference resistor 301. On top of the substrate 101 a thin dielectric layer (SiO₂) is fixed as a membrane 103. The reference resistor 301 is implemented on top of the membrane 103. According to this exemplified embodiment the reference resistor 301 is at least partially in a direct thermal contact with the substrate 101 through the membrane 103 (i.e. the insulating cavity does not extend underneath the reference resistor). This is realized in this manner in order to measure accurately the environmental temperature change of the dielectric waveguide. The thin dielectric (SiO₂) layer extends over the whole substrate because it is needed for the fabrication of the antenna element and on the other hand it provides an electrical insulation between the reference resistor, the antenna element and the substrate, which is important in a sense of accurate resistance measurement. FIG. 3 illustrates also at least part of the antenna element 105.

FIG. 3 discloses a cross sectional illustration of the exemplified implementation of the invention. In practice, the antenna element and the reference resistor are preferably positioned in such a manner that they are at least partially thermally isolated from each other.

According to an embodiment of the invention the reference resistor 301 is a small stripe of metal. Thus, it is possible to detect the effects of temperature change in the substrate 101 directly by means of reference resistor 301. As a result, the effect of the change in the environmental temperature can be taken into account in the power measurement in the dielectric waveguide. The resistance change of this reference resistor is measured using standard electrical engineering tools and this result is used to correct the power measurement result.

The material of the reference resistor, according to at least some embodiments of the invention, is the same material as the sensing element i.e. antenna structure. The benefit of this is that the reference resistor 301 provides the same temperature coefficient of resistance, which makes the definition of the power in the waveguide more straightforward. Additionally, this makes the fabrication process easier.

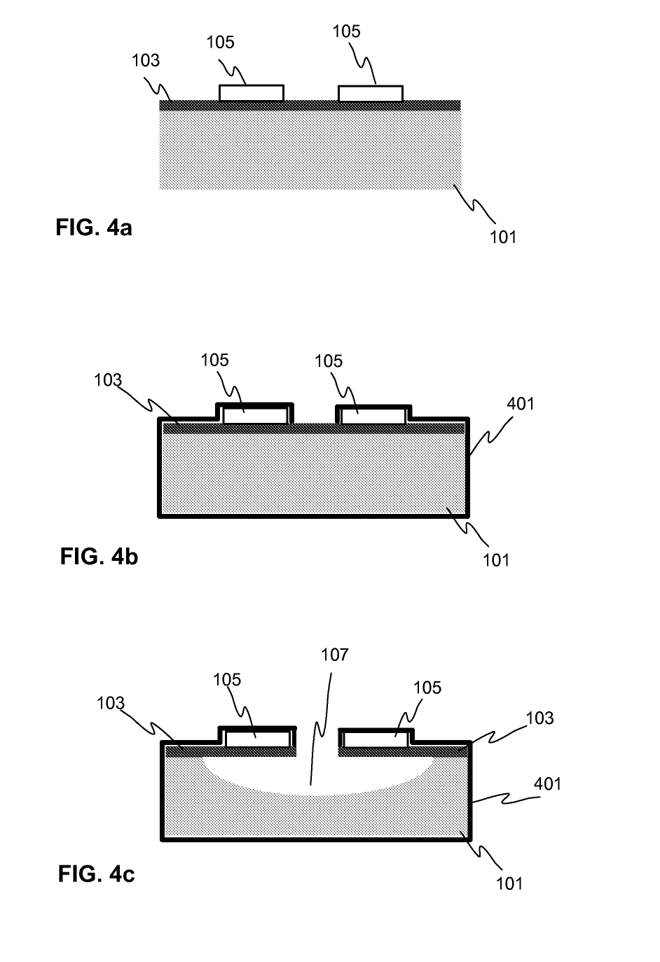

The invention also relates to fabrication method of the sensor into the Si dielectric waveguide. The fabrication of the power sensor according to an embodiment of the invention is based on well-established CMOS technology using silicon dry etch on a high-resistivity silicon substrate. The reference is now made to FIGS. 4a-4c disclosing a step-by-step visualization of the fabrication method according to an embodiment of the invention. The dielectric waveguide structure is used as a substrate 101 in the fabrication. The substrate 101 is capped with a membrane 103 as illustrated in FIG. 4a, the membrane 103 having such a size that the lossy antenna element 105 can be implemented on top of it. The lossy antenna element can be metallic according to at least some embodiment of the invention. FIGS. 4a-4c illustrate a metallic antenna element with two branches. Moreover, according to an embodiment the membrane 103 is fixed to the Si-based dielectric waveguide structure only by one edge forming a cantilever structure on the dielectric waveguide, as disclosed in FIGS. 4a-4c. The lossy antenna element 105 is placed on top of the membrane 103. According to some embodiment of the invention silicon (Si) under the membrane 103 and thus under the antenna element 105 is etched in order to gain a cavity/air gap 107 for thermal insulation purposes, as disclosed in FIG. 4c. The etching can be done by utilizing so called inductively coupled plasma reactive ion etching (ICP-RIE). Alternatively, one can use the wet etching of silicon in manufacturing process of the sensor solution according to the invention.

According to some embodiment of the invention the method comprises further a step of implementing a reference resistor on the surface of the membrane for detecting a temperature change caused by environmental changes. The reference resistor is implemented at least partially in a direct thermal contact with said substrate through said membrane, as discussed earlier. The fabrication of the reference resistor is made using the same techniques as with the other structures of the sensor. However, the insulating cavity, e.g. an air gap or vacuum space, under the reference resistor is not implemented. Thus, the reference resistor remains in thermal contact with the dielectric waveguide structure.

It will be appreciated by those skilled in the art that the present invention can be embodied in other specific forms without departing from the spirit or essential characteristics thereof. The described fabrication process is based on use of silicon and CMOS technology, but any other semiconductor material and related microfabrication process can be used. The presently disclosed embodiments are therefore considered in all respects to be illustrative and not restrictive. The scope of the invention is indicated by the appended claims rather than the foregoing description and all changes that come within the meaning and range and equivalence thereof are intended to be embraced therein.

What is claimed is:

1. A sensor for measuring electromagnetic power in a dielectric waveguide structure, comprising:
an antenna element for detecting heating caused by electromagnetic power absorbed into the antenna element;
wherein a membrane forming at least partially a thermally insulating layer is implemented on a surface of the dielectric waveguide structure being a substrate for said sensor;
wherein said antenna element is implemented on a surface of said membrane;
wherein said antenna element is at least partially thermally insulated from said substrate with a cavity.

2. A sensor as claimed in claim 1, further comprising a reference resistor for detecting a temperature change caused by environmental changes implemented on said surface of said membrane.

3. A sensor as claimed in claim 2, wherein said reference resistor is at least partially in a direct thermal contact with the substrate through said membrane.

4. A sensor as claimed in claim 2, wherein said reference resistor is a stripe of metal.

5. A sensor as claimed in claim 1, wherein said antenna element is metallic.

6. A sensor as claimed in claim 2, wherein said antenna element and said reference resistor are manufactured of the same metallic material.

7. A sensor as claimed in claim 1, wherein said membrane silicon dioxide (SiO₂).

8. A sensor as claimed in claim 1, wherein the depth of said cavity is of the order of 50 μm.

9. A sensor as claimed in claim 1, wherein said cavity is one of the following:
air gap, vacuum space.

10. A method for fabricating a sensor for measuring electromagnetic power in a dielectric waveguide structure, comprising:
capping at least partially the dielectric waveguide structure with a membrane, the dielectric waveguide structure forming a substrate for the sensor;
implementing an antenna element at least partially on a surface of the membrane;
etching said dielectric waveguide structure at least partially below said antenna element in order to thermally insulate the antenna element from said substrate by forming an insulating cavity.

11. A method as claimed in claim 10, further comprising
implementing a reference resistor on said surface of said membrane for detecting a temperature change caused by environmental changes, wherein said reference resistor is implemented at least partially in a direct thermal contact with said substrate through said membrane.

12. A method as claimed in claim 10, wherein said etching is achieved by inductively coupled plasma reactive ion etching (ICP-RIE).

13. A method as claimed in claim 10, wherein said etching is achieved by wet etching of silicon.
